(19) United States
(12) Patent Application Publication
(10) Pub. No.: US 2016/0284395 A1
(43) Pub. Date: Sep. 29, 2016

(54) 2-BIT FLASH MEMORY DEVICE AND PROGRAMMING, ERASING AND READING METHODS THEREOF

(71) Applicants: Jinglun Gu, Shanghai (CN); Jiang Yan, Shanghai (CN)

(72) Inventors: Jinglun Gu, Shanghai (CN); Jiang Yan, Shanghai (CN)

(21) Appl. No.: 14/753,271

(22) Filed: Jun. 29, 2015

(30) Foreign Application Priority Data
Mar. 23, 2015 (CN) 201510128268.8

(51) Int. Cl. G11C 11/56; H01L 29/49; H01L 29/423; H01L 29/51; H01L 29/788; H01L 27/115

(52) U.S. Cl. CPC G11C 11/5628; G11C 11/5635; G11C 11/5642; H01L 29/7885; H01L 27/11521; H01L 29/42328; H01L 29/51; H01L 29/4916

(57) ABSTRACT

The present invention discloses a 2-bit flash memory device comprising a P-type substrate which has a source and a drain, and first and second floating gates which are successively located on the upper and lower sides of the substrate. The first and second floating gates are N-type doped polysilicon, the first control gate is P-type polysilicon, and the second control gate is N-type polysilicon. The present invention can expand the storage capacity per unit area of a floating gate flash memory, thus reducing the dimension of the floating gate flash memory.

### CROSS-REFERENCE TO RELATED APPLICATION

This application claims the priority benefit of China patent application Ser. No. 201510128268.8, filed Mar. 23, 2015. The entirety of each of the above-mentioned patent applications is hereby incorporated by reference herein and made a part of this specification.

### FIELD OF THE INVENTION

The present invention relates to the field of semiconductor technology, and more specifically to a 2-bit flash memory device of double-gate type and programming, erasing and reading methods thereof.

### BACKGROUND OF THE INVENTION

Among semiconductor memory devices, a flash memory is a long-life nonvolatile (i.e., still able to hold the stored data information in the case of power off) memory. The flash memory is a variant of an electronic erasable read-only memory (EEPROM). Since the flash memory can still save data when powered off, it can usually be used to save setting information, for example, to save data in BIOS (base program) of a computer, a PDA (personal digital assistant) and a digital camera, and so on. The flash memory is characterized by being able to perform a fast erasing operation in units of sector. A writing operation of the flash memory must be performed in a blank area. If the data already exists in a target area, erasing operation must be done before writing operation. Therefore, the erasing operation is a basic operation of the flash memory.

The predominant nonvolatile flash memory structures at present are all single control gate structures, such as floating gate flash memory and SONOS structures. Due to the floating gate flash memory structure of the single gate, each memory cell can only be distinguished between two different states, i.e., “0” and “1”. Thus, each memory cell only has a storage capacity of 2 bits. Moreover, currently, the dimension reduction of the flash memory is behind the logic device by one to two generations over a long period of time. For example, at present, Intel has developed a FinFET of 14 nm, while the dimension of the flash memory still stops at about 50 nm.

The literature “A Highly Scalable 2-Bit Asymmetric Double-Gate MOSFET Nonvolatile Memory” proposes a double-gate SONOS device in which a 2-bit memory can be constructed with a double-gate structure. This can increase the storage density of the SONOS, because a 2-bit memory cell can store 4 states which are “00”, “01”, “10” and “11” respectively. Thus, the storage capacity of the entire memory array is increased exponentially relative to the single-gate memory.

The double-gate structure is one of the candidates with which the MOSFET can suppress the short channel effect well in the process of dimension reduction. According to the discussion of the literature “A Highly Scalable 2-Bit Asymmetric Double-Gate MOSFET Nonvolatile Memory_{[1]}” described above, the research data shows that a MOSFET of double-gate structure can reduce the dimension of a MOSFET to 5 nm. That is to say, the flash memory of double-gate structure also has the potential to reduce the dimension to the limit of 5 nm.

Therefore, the industry is constantly trying to research a new 2-bit flash memory device of double-gate type, and expects to perform information storage using 2-bit, so as to effectively carry out the dimension reduction of the flash memory.

[1] Kam Hung Yuen, Tsz Yin Man, 2003 IEEE Conference on Electron Devices and Solid-State Circuits, p.59

### BRIEF SUMMARY OF THE DISCLOSURE

The object of the present invention is to overcome the above drawbacks existing in the prior art, provides a 2-bit flash memory device and programming, erasing and reading methods thereof, and can expand the storage capacity per unit area of a floating gate flash memory, thus reducing the dimension of the floating gate flash memory to 50 nm or less.

To achieve the above object, the technical scheme of the present invention is as follows:

A 2-bit flash memory device comprising: a semiconductor substrate which includes an N-type doped source and drain located at both ends, and a P-type silicon channel located in the middle;

first and second floating gates which are respectively located on the upper and lower sides of the substrate between the source and the drain, and the first and second control gates which are respectively located outside the first and second floating gates, a silicon dioxide layer existing between the control gates and the floating gates, a silicon dioxide gate oxide layer existing between the floating gates and the substrate, the first and second floating gates being N-type doped polysilicon, the first control gate being P-type polysilicon, and the second control gate being N-type polysilicon;

wherein, when the 2-bit flash memory device is in programming, by applying a positive drain voltage the drain, making the source grounded, and defining the state of electrons being stored in the corresponding floating gate to be “1”, and if an “1” state is programmed on any one of the control gates, applying a positive gate voltage to the corresponding control gate, the channel of the substrate generates an electron inversion layer, and under the action of acceleration of the drain voltage, the channel electrons gain sufficient energy to cross a barrier between the gate oxide layers and the substrate silicon, thus becoming hot electrons, and under the action of the gate voltage, the hot electrons are injected into the floating gates, thus completing the programming.

Preferably, the first and second floating gates, the first and second control gates, and the silicon dioxide layers and the silicon dioxide gate oxide layers are disposed symmetrically in geometric dimensions, on the upper and lower sides of the substrate between the source and the drain.

Preferably, the thickness of the first and second floating gates is 45˜55 nm, the thickness of the first and second control gates is 85˜95 nm, the thickness of the silicon dioxide layers is 3˜10 nm, and the thickness of the silicon dioxide gate oxide layers is 2˜5 nm.

Preferably, when the 2-bit flash memory device is in programming, a drain voltage of 4.5˜5 V is applied to the drain, the source is applied with 0 V to be grounded, and if an “1” state is programmed on any one of the control gates, a gate voltage of 4.5˜5 V is applied to the corresponding control gate.

Programming, erasing and reading methods of a 2-bit flash memory device, the 2-bit flash memory device comprising: a semiconductor substrate which has an N-type doped source and drain located at both ends and a P-type silicon channel located in the middle; first and second floating gates which are respectively located on the upper and lower sides of the substrate between the source and the drain, and first and second control gates which are respectively located outside the first and second floating gates, there is a silicon dioxide layer between the control gates and the floating gates, there is a silicon dioxide gate oxide layer between the floating gates and the substrate, the first and second floating gates are N-type doped polysilicon, the first control gate is P-type polysilicon, and the second control gate is N-type polysilicon;

the programming method comprising: performing in a manner of channel hot electron injection, and in programming, a positive drain voltage is applied to the drain, the source is grounded, and the state of electrons being stored in the corresponding floating gate is defined to be “1”, and if an “1” state is programmed on any one of the control gates, a positive gate voltage is applied to the corresponding control gate, so that the channel of the substrate generates an electron inversion layer, and under the action of acceleration of the drain voltage, the channel electrons gain sufficient energy to cross a barrier between the gate oxide layers and the silicon substrate, thus becoming hot electrons, and under the action of the gate voltage, the hot electrons are injected into the floating gates, thus completing the programming;

the easing method comprising: performing using the FN tunneling mechanism of electron, and when erasing the first floating gate, a negative gate voltage is applied to the first control gate, a positive gate voltage is applied to the second control gate, and the source and the drain are both grounded, so as to form one strong electric field between the second control gate and the first control gate, and, under the action of this strong electric field, to cause the electrons in the first floating gate to be erased by the FN tunneling mechanism;

the reading method comprising: making the. source grounded, applying a positive drain voltage to the drain, making the first and second control gates short-circuited and applying the same positive voltage to the first and second control gates, and obtaining read current-control gate voltage curves of four states of “00”, “01”, “10” and “11” by performing scanning for voltage in ascending order.

Preferably, the first and second floating gates, the first and second control gates, and the silicon dioxide layers and the silicon dioxide gate oxide layers are disposed symmetrically in geometric dimensions, on the upper and lower sides of the substrate between the source and the drain.

Preferably, the thickness of the first and second floating gates is 45˜55 nm, the thickness of the first and second control gates is 85˜95 nm, the thickness of the silicon dioxide layers is 3˜10 nm, and the thickness of the silicon dioxide gate oxide layers is 2˜5 nm.

Preferably, in the programming method, when programming, a drain voltage of 4.5˜5 V is applied to the drain, the source is applied with 0 V to be grounded, and if an “1” state is programmed on any one of the control gates, a gate voltage of 4.5˜5 V is applied to the corresponding control gate.

Preferably, in the erasing method, when erasing the first floating gate, a gate voltage of −8˜12 V is applied to the first control gate, a gate voltage of 4.5˜5 V is applied to the second control gate, and the source and the drain are applied with 0 V simultaneously to be grounded.

Preferably, in the reading method, the source is applied with 0 V to be grounded, a drain voltage of 1˜1.5 V is applied to the drain, the first and second control gates are short-circuited and are applied with the same gate voltage of 0˜3 V, and the read current-control gate voltage curves of four states of “00”, “01”, “10” and “11” are obtained by performing voltage scanning of 0∞3 V.

The beneficial effects of the present invention are as follows: the 2-bit flash memory device of the present invention has the dimension reduction advantage of the double-gate MOSFET structure, and can reduce the critical dimension to 50 nm or less; the two control gates can provide information storage of 2-bit, i.e., can increase the storage capacity per unit area of the floating flash memory, that is, increases the storage density.

### BRIEF DESCRIPTION OF THE DRAWINGS

FIG. 1 is a schematic structure diagram of a 2-bit flash memory device of an embodiment of the present invention;

FIG. 2 is a read current-control gate voltage curve of the 2-bit flash memory device, which is obtained by TCAD (Technology Computer Aided Design) simulation.

### DETAILED DESCRIPTION OF THE EMBODIMENTS

The specific embodiments of the present invention is explained in further detail below with reference to the accompanying drawings.

It should be noted that, in the following specific embodiments, when the embodiments of the present invention are described in detail, in order to clearly illustrate the structure of the present invention to facilitate the explanation, specially for the structures in the drawings, the drawing is not made in accordance with the general ratio, and local enlargement, deformation and simplification processing is made. Therefore, it should be avoided to understand this as a limitation on the present invention.

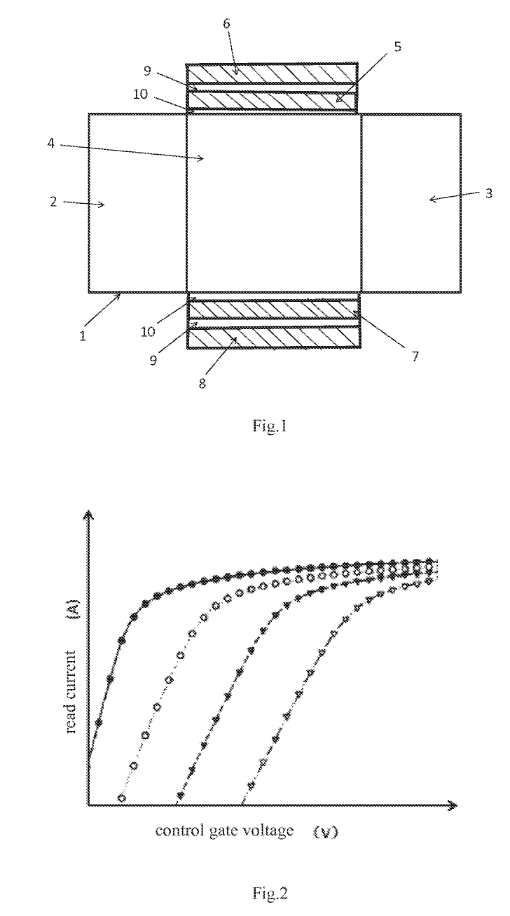

In the specific embodiments of the present invention below, please refer to FIG. 1. FIG. 1 is a schematic structure diagram of a 2-bit flash memory device of an embodiment of the present invention. As shown in FIG. 1, a 2-bit flash memory of the present invention comprises a semiconductor substrate 1 which includes an N-type doped source 2 and drain 3 located at both ends and a P-type silicon channel 4 located in the middle; and comprises first and second floating gates 5, 7 which are respectively located on the upper and lower sides of the substrate 1 between the source 2 and the drain 3, and the first and second control gates 6, 8 which are respectively located outside the first and second floating gates 5, 7. There is a silicon dioxide layer 9 between the control gates and the floating gates, and there is a silicon dioxide gate oxide layer 10 between the floating gates and the substrate 1. The first and second floating gates 5, 7 are N-type doped polysilicon, the first control gate 6 is P-type polysilicon, and the second control gate 8 is N-type polysilicon.

As a preferred embodiment, the first and second floating gates 5, 7, the first and second control gates 6, 8, and the silicon dioxide layers 9 and the silicon dioxide gate oxide layers 10 are disposed symmetrically in geometric dimensions, on the upper and lower sides of the substrate 1 between the source 2 and the drain 3. Further alternatively, the first and second floating gates 5, 7 symmetrically have the same thickness between 45˜55 nm; the first and second control gates 6, 8 symmetrically have the same thickness between 85˜95 nm, the silicon dioxide layers 9 on both sides of the substrate 1 symmetrically have the same thickness between 3˜10 nm, and the silicon dioxide gate oxide layers 10 on both sides symmetrically have the same thickness between 2˜5 nm.

When programming is performed on the above-mentioned 2-bit flash memory device, this programming method comprises: performing in a manner of channel hot electron (CHE) injection. In programming, a positive drain voltage is applied to the drain 3, the source 2 is grounded, and the state of electrons being stored in the corresponding floating gate is defined to be “1”. If an “1” state is programmed on any one of the control gates, a positive gate voltage is applied to the corresponding control gate, so that the channel 4 of the substrate 1 generates an electron inversion layer. Under the action of acceleration of the voltage of the drain 3, the channel electrons gain sufficient energy to cross a barrier between the gate oxide layers and the silicon substrate, thus becoming hot electrons. Under the action of the gate voltage, the hot electrons are injected into the floating gates, thus completing the programming.

As an alternative embodiment, in the above programming method, when programming, a drain voltage of 4.5˜5 V is applied to the drain 3, and the source 2 is applied with 0 V to be grounded. If a “1” state is programmed on any one of the control gates, a gate voltage of 4.5˜5 V is applied to the corresponding control gate. For example, as an instance, in programming, a voltage of 4.5 V is applied to the drain 3, and the source 2 is applied with 0 V to be grounded. We define the state of electrons being stored in the corresponding floating gate to be “1”. To program a “1” sate on any one of the control gates, a voltage of 4.5 V must be applied to the corresponding control gate. For instance, to program a “1” state on the first control gate 6, a voltage of 4.5 V must be applied to the first control gate 6. After a voltage of 4.5 V is applied to a certain control gate, the channel produces an electron inversion layer. Under the action of acceleration of the drain voltage, the channel electrons gain sufficient energy to cross a barrier between the gate oxide layers and the silicon, thus becoming hot electrons. Under the action of the gate voltage, the hot electrons are injected into the floating gates, thus completing the programming.

When erasing is performed on the above-mentioned 2-bit flash memory device, this easing method comprising: performing using the FN (Fowler-Nordheim) tunneling mechanism of electron. The reason for selecting electron FN tunneling as the erasing mechanism is that it avoids the problem in the reliability of the hot hole injection mechanism. When erasing the first floating gate 5, a negative gate voltage is applied to the first control gate 6, a positive gate voltage is applied to the second control gate 8, and the source and drain 2, 3 are both grounded, so as to form one strong electric field between the second control gate 8 and the first control gate 6, and, under the action of this strong electric field, to cause the electrons in the first floating gate 5 to be erased by the FN tunneling mechanism.

As an alternative embodiment, in the above erasing method, when erasing the first floating gate 5, a gate voltage of −8˜12 V is applied to the first control gate 6, a gate voltage of 4.5˜5 V is applied to the second control gate 8, and the source and drain 2, 3 are applied with 0 V simultaneously to be grounded. For example, as an instance, when erasing the first floating gate 5, a gate voltage of −8 V is applied to the first control gate 6, a gate voltage of 5 V is applied to the second control gate 8, and the source and drain 2, 3 are both applied with 0 V to be grounded. So at this time, there is one strong electric field between the second control gate 8 and the first control gate 6. Under the action of this strong electric field, the electrons in the first floating gate 5 are erased by the FN tunneling mechanism. Since the source and drain 2, 3 are both in a grounded state, the hot electron current to the second control gate 8 will not be produced, and the net current will not be produced at the source and drain 2, 3 either.

When reading is performed on the above-mentioned 2-bit flash memory device, this reading method comprising: making the source 2 grounded, applying a positive drain voltage to the drain 3, making the first and second control gates 6, 8 short-circuited and applying the same positive voltage thereto, and obtaining read current-control gate voltage curves of four states of “00”, “01”, “10” and “11” by performing scanning for voltage in ascending order.

As an alternative embodiment, in the above reading method, the source 2 is applied with 0 V to be grounded, a drain voltage of 1˜1.5 V is applied to the drain 3, the first and second control gates 6, 8 are short-circuited and are applied with the same gate voltage of 0˜3 V, and the read current-control gate voltage curves of four states of “00”, “01”, “10” and “11” are obtained by performing voltage scanning of 0˜3 V. For example, as an instance, the source 2 is applied with 0 V to be grounded, a drain voltage of 1 V is applied to the drain 3, the first and second control gates 6, 8 are short-circuited and are applied with the same voltage between 0˜3 V, and scanning is performed for this voltage from 0 V to 3 V. The read current-control gate voltage curves (Id-Vg curves) are obtained by voltage scanning. As shown in FIG. 2, four I-V curves from left to right in the figure, which correspond to the four logic states of “00”, “01”, “10” and “11”, can be seen. After the TCAD simulation, we obtain the read current-control gate voltage curves of the device structure of the 2-bit flash memory device of the present invention.

In summary, the 2-bit flash memory device of the present invention has the dimension reduction advantage of the double-gate MOSFET structure, and can reduce the critical dimension to 50 nm or less; the two control gates can provide information storage of 2-bit, i.e., can increase the storage capacity per unit area of the floating flash memory, that is, increases the storage density.

The above are only preferred embodiments of the present invention, and the embodiments are not intended to limit the patent protection scope of the present invention. Therefore, any equivalent structural change made using the contents of the description and the drawings of the present invention should be encompassed within the protection scope of the present invention in like manner.

1. A 2-bit flash memory device, comprising:
a semiconductor substrate which includes an N-type doped source and drain located at both ends, and a P-type silicon channel located in the middle;
first and second floating gates which are respectively located on the upper and lower sides of the substrate between the source and the drain, and first and second control gates which are respectively located outside the first and second floating gates, a silicon dioxide layer existing between the control gates and the floating gates, a silicon dioxide gate oxide layer existing between the floating gates and the substrate, the first and second floating gates being N-type doped polysilicon, the first control gate being P-type polysilicon, and the second control gate being N-type polysilicon;
wherein, when the 2-bit flash memory device is in programming, by applying a positive drain voltage the drain, making the source grounded, and defining the state of electrons being stored in the corresponding floating gate to be “1”, and if an “1” state is programmed on any one of the control gates, applying a positive gate voltage to the corresponding control gate, the channel of the substrate generates an electron inversion layer, and under the action of acceleration of the drain voltage, the channel electrons gain sufficient energy to cross a barrier between the gate oxide layers and the silicon substrate, thus becoming hot electrons, and under the action of the gate voltage, the hot electrons are injected into the floating gates, thus completing the programming.

2. The 2-bit flash memory device according to claim 1, wherein the first and second floating gates, the first and second control gates, and the silicon dioxide layers and the silicon dioxide gate oxide layers are disposed symmetrically in geometric dimensions, on the upper and lower sides of the substrate between the source and the drain.

3. The 2-bit flash memory device according to claim 2, wherein the thickness of the first and second floating gates is 45˜55 nm.

4. The 2-bit flash memory device according to claim 3, wherein the thickness of the first and second floating gates is 50 nm.

5. The 2-bit flash memory device according to claim 2, wherein the thickness of the first and second control gates is 85˜95 nm.

6. The 2-bit flash memory device according to claim 5, wherein the thickness of the first and second control gates is 90 nm.

7. The 2-bit flash memory device according to claim 2, wherein the thickness of the silicon dioxide layers is 3˜10 nm.

8. The 2-bit flash memory device according to claim 7, wherein the thickness of the silicon dioxide layers is 6 nm.

9. The 2-bit flash memory device according to claim 2, wherein the thickness of the silicon dioxide gate oxide layers is 2˜5 nm.

10. The 2-bit flash memory device according to claim 9, wherein the thickness of the silicon dioxide gate oxide layers is 3 nm.

11. The 2-bit flash memory device according to claim 2, wherein the thickness of the first and second floating gates is 45˜55 nm, the thickness of the first and second control gates is 85˜95 nm, the thickness of the silicon dioxide layers is 3˜10 nm, and the thickness of the silicon dioxide gate oxide layers is 2˜5 nm.

12. The 2-bit flash memory device according to claim 1, wherein the thickness of the first and second floating gates is 45˜55 nm, the thickness of the first and second control gates is 85˜95 nm, the thickness of the silicon dioxide layers is 3˜10 nm, and the thickness of the silicon dioxide gate oxide layers is 2˜5 nm.

13. The 2-bit flash memory device according to claim 1, wherein when the 2-bit flash memory device is in programming, a drain voltage of 4.5˜5 V is applied to the drain, the source is applied with 0 V to be grounded, and if an “1” state is programmed on any one of the control gates, a gate voltage of 4.5˜5 V is applied to the corresponding control gate.

14. Programming, erasing and reading methods of a 2-bit flash memory device, wherein the 2-bit flash memory device comprises: a semiconductor substrate which has an N-type doped source and drain located at both ends and a P-type silicon channel located in the middle; first and second floating gates which are respectively located on the upper and lower sides of the substrate between the source and the drain, and first and second control gates which are respectively located outside the first and second floating gates, there is a silicon dioxide layer between the control gates and the floating gates, there is a silicon dioxide gate oxide layer between the floating gates and the substrate, the first and second floating gates are N-type doped polysilicon, the first control gate is P-type polysilicon, and the second control gate is N-type polysilicon;
the programming method comprises: performing in a manner of channel hot electron injection, and in programming, a positive drain voltage is applied to the drain, the source is grounded, and the state of electrons being stored in the corresponding floating gate is defined to be “1”, and if an “1” state is programmed on any one of the control gates, a positive gate voltage is applied to the corresponding control gate, so that the channel of the substrate generates an electron inversion layer, and under the action of acceleration of the drain voltage, channel electrons gain sufficient energy to cross a barrier between the gate oxide layers and the substrate silicon, thus becoming hot electrons, and under the action of the gate voltage, the hot electrons are injected into the floating gates, thus completing the programming;
the easing method comprises: performing using the FN tunneling mechanism of electron, and when erasing the first floating gate, a negative gate voltage is applied to the first control gate, a positive gate voltage is applied to the second control gate, and the source and the drain are both grounded, so as to form one strong electric field between the second control gate and the first control gate, and, under the action of this strong electric field, to cause the electrons in the first floating gate to be erased by the FN tunneling mechanism;
the reading method comprises: making the source grounded, applying a positive drain voltage to the drain, making the first and second control gates short-circuited and applying the same positive voltage to the first and second control gates, and obtaining read current-control gate voltage curves of four states of “00”, “01”, “10” and “11” by performing scanning for voltage in ascending order.

15. The methods according to claim 14, wherein the first and second floating gates, the first and second control gates, and the silicon dioxide layers and the silicon dioxide gate oxide layers are disposed symmetrically in geometric dimensions, on the upper and lower sides of the substrate between the source and the drain.

16. The methods according to claim 14, wherein the thickness of the first and second floating gates is 45˜55 nm, the thickness of the first and second control gates is 85˜95 nm, the thickness of the silicon dioxide layers is 3˜10 nm, and the thickness of the silicon dioxide gate oxide layers is 2˜5 nm.

17. The methods according to claim 15, wherein the thickness of the first and second floating gates is 45˜55 nm, the thickness of the first and second control gates is 85˜95 nm, the thickness of the silicon dioxide layers is 3˜10 nm, and the thickness of the silicon dioxide gate oxide layers is 2˜5 nm.

14. methods according to claim 14, wherein, in the programming method, when programming, a drain voltage of 4.5˜5 V is applied to the drain, the source is applied with 0 V to be grounded, and if an “1” state is programmed on any one of the control gates, a gate voltage of 4.5˜5 V is applied to the corresponding control gate.

19. The methods according to claim 14, wherein, in the erasing method, when erasing the first floating gate, a gate voltage of −8˜12 V is applied to the first control gate, a gate voltage of 4.5˜5 V is applied to the second control gate, and the source and the drain are applied with 0 V simultaneously to be grounded.

20. The methods according to claim 14, wherein, in the reading method, the source is applied with 0 V to be grounded, a drain voltage of 1˜1.5 V is applied to the drain, the first and second control gates are short-circuited and are applied with the same gate voltage of 0˜3 V and the read current-control gate voltage curves of four states of “00”, “01”, “10” and “11” are obtained by performing voltage scanning of 0˜3 V.
